(19) United States
(12) Patent Application Publication
(10) Pub. No.: US 2014/0224767 A1
(43) Pub. Date: Aug. 14, 2014

(54) AUTOMATED ALGORITHM FOR TUNING OF FEEDFORWARD CONTROL PARAMETERS IN PLASMA PROCESSING SYSTEM

(71) Applicants: Walter R. MERRY, Sunnyvale, CA (US); Sergio Fukuda SHOJI, San Jose, CA (US); Yang YANG, Los Gatos, CA (US); Duy D. NGUYEN, Milpitas, CA (US); Justin PHI, Milpitas, CA (US)

(72) Inventors: Walter R. MERRY, Sunnyvale, CA (US); Sergio Fukuda SHOJI, San Jose, CA (US); Yang YANG, Los Gatos, CA (US); Duy D. NGUYEN, Milpitas, CA (US); Justin PHI, Milpitas, CA (US)

(21) Appl. No.: 14/179,749

(22) Filed: Feb. 13, 2014

Related U.S. Application Data
(60) Provisional application No. 61/764,464, filed on Feb. 13, 2013.

(51) Int. Cl. C23F 1/08; C23C 16/50

(52) U.S. Cl. CPC C23F 1/08; C23C 16/50
USPC 216/59; 427/569; 156/345.24; 118/696

(57) ABSTRACT

Methods and systems for adapting and/or tuning feedforward control parameters in a plasma processing chamber. In embodiments, a dependent process parameter, such as a chamber component temperature, is controlled with a feedforward control algorithm based on one or more independent process parameters, such as RF power. A control algorithm may calculate steady-state deviation of the dependent parameter from a process recipe setpoint, estimate an amount by which an existing control gain coefficient is to be changed to better achieve the setpoint, associate the new control gain coefficient with the particular recipe operation, and store the new control gain coefficient for subsequent execution of the recipe operation. In embodiments, the amount by which a gain coefficient is to be changed is based on a model function derived from a lookup table associating gain coefficients with setpoints of the dependent process parameter and values of the independent process parameter.

### CROSS-REFERENCE TO RELATED APPLICATIONS

This application is a Non-Provisional of, claims priority to, and incorporates by reference in its entirety for all purposes, the U.S. Provisional Patent Application No. 61/764,464 filed Feb. 13, 2014. This application is related to U.S. patent application Ser. No. 13/111,334, titled “TEMPERATURE CONTROL IN PLASMA PROCESSING APPARATUS USING PULSED HEAT TRANSFER FLUID FLOW,” filed May 19, 2011.

### BACKGROUND

1. Field

Embodiments of the present invention generally relate to plasma processing equipment, and more particularly to methods of controlling process parameters during processing of a workpiece with a plasma processing chamber.

2. Description of Related Art

In a plasma processing chamber, such as a plasma etch or plasma deposition chamber, a process parameter, such as the temperature of a chamber component, is often important to control during a process. U.S. patent application Ser. No. 13/111,334 referenced above and commonly assigned, describes a pulsed heat transfer fluid control technology, which employs both a feedforward control loop that takes into consideration an effect of plasma heating of the process chamber, and a feedback control loop that takes into consideration an offset between a measured temperature and a set point temperature. As described, gain coefficients are required for each control loop (e.g., Kᵤ, Kᵥ).

While the gain coefficients may be determined manually by empirical trial and error testing, accurate feedforward temperature control (specifically, steady-state temperature) is difficult because the coefficients are unique to a specific chamber with its exact chillers, hoses, ESC and “water-FIB”. Furthermore, on the same chamber, plasma process recipes which use different process parameters (e.g., RF power) generally necessitate slightly different values to achieve accurate agreement between a steady state process temperature and a recipe setpoint temperature. This is because the actual plasma heating of the cathode has modest physical dependence variables other than plasma power. Thus, many gain coefficients may be needed within a given process, recipe, many more across a portfolio of recipes on each process chamber, and even more across a group of chambers qualified to perform a given process.

Accordingly, a system capable of automatic tuning and adaptation of the feedforward control system parameters would advantageously afford greater chamber performance and/or operational up time.

### SUMMARY

Disclosed herein is a model-based adaptive feedforward control system that may control a dependent process parameter such as a chamber component temperature, pressure, RF impedance matching (either by tuning of capacitor or by tuning RF frequency), RF voltage, electrostatic chucking voltage or other process variable of a plasma processing apparatus. In embodiments, the feedforward control loop employs gain coefficients that are dynamically updated during processing. Such updates may be conditioned on a determination that the dependent process parameter value is in a steady state condition that deviates from a desired target or setpoint. Such updates may be premised on a model function derived from a lookup table that associates gain values with setpoints of the dependent process parameter correlated to values of the independent process parameter. A derivative of the gain coefficient with respect to the setpoint may be estimated to determine an updated gain coefficient. While many details are provided in the context of temperature control as a vehicle for conveying a complete description, the embodiments described herein may be readily extended to any measurable process parameter which is capable of undergoing an approach to steady state in some appropriate period of time and is associated with a feedforward gain coefficient that can be altered to effect a change in a manipulated variable to trigger predictable change in a process variable of relevance to the measurable variable.

Embodiments further include a computer readable media storing instructions which when executed by a processing system cause the processing system to coordinate heat transfer between the process chamber and a heat sink and/or a heat source. In one such embodiment, computer readable media stores instructions to at least calculate the deviation of a steady-state temperature from the recipe setpoint, estimate an amount by which an existing gain coefficient is to be changed to better achieve the setpoint, associate the new gain coefficient with the particular recipe operation, and store the new control gain coefficient. In further embodiments, the new gain coefficient is implemented while the process recipe that was executing during determination of the new coefficient continues to execute. Substantially real-time adaptation of a gain coefficient used in the control system is achieved.

Embodiments include a plasma processing chamber, such as a plasma etch or plasma deposition system, having a temperature-controlled component and a temperature controller to execute a temperature control algorithm that employs control gain coefficients that are updated based on an estimate of an amount by which a prior control gain coefficient is to be changed to better achieve the setpoint. In embodiments, automated service routines are performed to adapt gain coefficients to a particular chamber over a pre-determined process space.

### BRIEF DESCRIPTION OF THE DRAWINGS

Embodiments of the present invention are illustrated by way of example, and not limitation, in the figures of the accompanying drawings in which:

FIG. 1 is a block diagram illustrating a temperature control system including both feedforward and feedback control elements and providing an adaptive tuning of at least one control parameter, in accordance with an embodiment of the present invention;

FIG. 2A illustrates a schematic of a plasma etch system including a temperature controller configured to implement adaptive tuning of a process gas showerheard temperature control, in accordance with an embodiment of the present invention;

FIG. 2B illustrates a schematic of a plasma etch system including a temperature controller configured to implement adaptive tuning of a workpiece chuck temperature control, in accordance with an embodiment of the present invention;

FIG. 3 is a flow diagram illustrating operations in a computer implemented method for adaptive tuning of a temperature control parameter in the plasma etch system depicted in FIG. 2, in accordance with an embodiment of the present invention;

FIG. 4A is a flow diagram illustrating operations in a computer implemented method for initiating the adaptive tuning method depicted in FIG. 3, in accordance with an embodiment of the present invention;

FIG. 4B is a flow diagram illustrating operations invoked by the computer implemented method depicted in FIG. 3, in accordance with an embodiment of the present invention;

FIG. 4C is a gain coefficient group lookup table (LUT), in accordance with an embodiment of the present invention; and

FIG. 5 illustrates a block diagram of an exemplary computer system incorporated into the plasma etch system depicted in FIG. 2A and configured to execute an adaptive tuning of a temperature control parameter in a plasma processing system, in accordance with one embodiment of the present invention.

### DETAILED DESCRIPTION

In the following detailed description, numerous specific details are set forth in order to provide a thorough understanding of embodiments of the invention. However, it will be understood by those skilled in the art that other embodiments may be practiced without these specific details. In other instances, well-known methods, procedures, components and circuits have not been described in detail so as not to obscure the present invention. Some portions of the detailed description that follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

An algorithm or method is generally considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, levels, numbers or the like. It should be understood, however, that all of these and similar terms are to be associated with the appropriate physical quantities and are merely convenient labels applied to these quantities.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Embodiments of the present invention may include apparatuses for performing the operations herein. An apparatus may be specially constructed for the desired purposes, or it may comprise a general purpose computing device selectively activated or reconfigured by a program stored in the device. Such a program may be stored on a storage medium, such as, but not limited to, any type of disk including floppy disks, optical disks, compact disc read only memories (CD-ROMs), magnetic-optical disks, read-only memories (ROMs), random access memories (RAMs), electrically programmable read-only memories (EPROMs), electrically erasable and programmable read only memories (EEPROMs), magnetic or optical cards, or any other type of media suitable for storing electronic instructions, and capable of being coupled to a system bus for a computing device.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” my be used to indicated that two or more elements are in either direct or indirect (with other intervening elements between them) physical or electrical contact with each other, and/or that the two or more elements co-operate or interact with each other (e.g., as in a cause and effect relationship).

Embodiments of methods and systems for controlling a dependent process parameter with a feedforward control loop based at least in part on an independent process parameter are described herein. The feedforward control loop employs gain coefficients that are dynamically updated during processing. Such updates may be conditioned on a determination that the dependent process parameter value is in a steady state condition that deviates from a desired target or setpoint. Such updates may be premised on a model function derived from a lookup table that associates gain values with setpoints of the dependent process parameter correlated to values of the independent process parameter. A derivative of the gain coefficient with respect to the setpoint may be estimated to determine an updated gain coefficient.

In certain embodiments, a temperature control effort including both a cooling control loop and a heating control loop in which heat source and sink is to maintain a setpoint temperature (as a “dependent process parameter”) when confronted with an external disturbance by an “independent process parameter.” Generally, a plasma process chamber (module) controller provides a level of temperature control above the conventional independent heat sink/heat source controllers. The chamber level controller executes a temperature control algorithm and communicates control parameters, such as feedback and/or feedforward gain values to one or more of the heat sink/heat source controllers to effect control of, for example, a coolant liquid flow control, and/or heater duty cycle. In embodiments, the controller further executes a temperature control algorithm that detects when a steady state temperature error is present, and in response, modifies at least one feedforward gain value to mitigate the error.

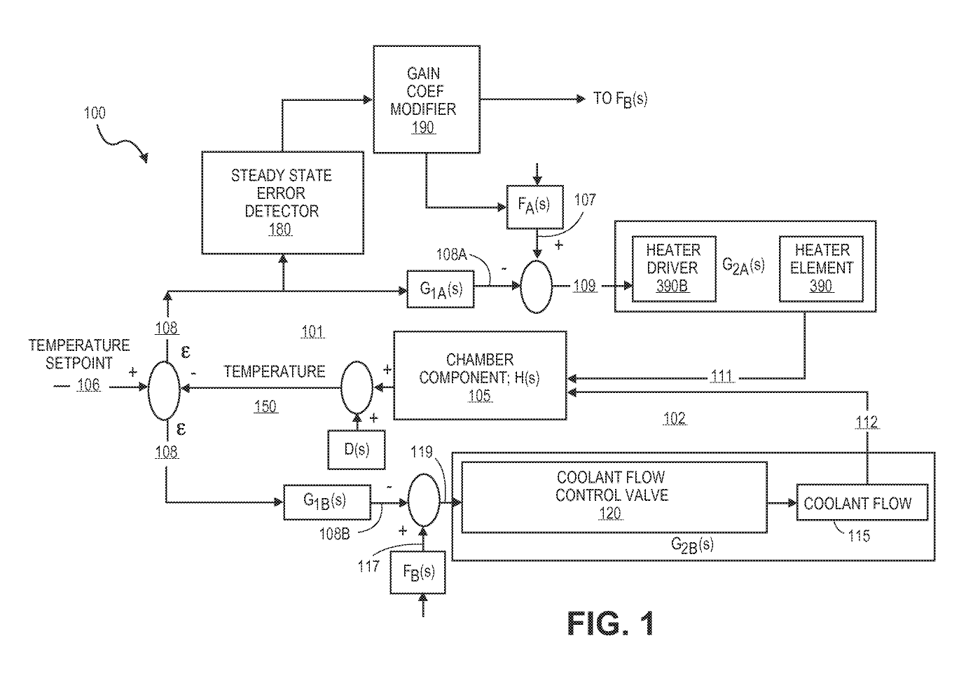

One or more of discrete controllers may operate in a manual mode merely as a driver of the control actuators (e.g., valves, resistive elements, etc.) operating under the direction of the integrated plasma chamber control software executing instructions implementing the control system 100 depicted in FIG. 1. Control system 100 includes both feedforward and feedback control elements coordinating control efforts 111, 112 responsive to disturbances. In embodiments, the architecture depicted in FIG. 1 is replicated for each separately controlled parameter or component 105 (e.g., wafer support chuck, chamber showerhead, etc.). In embodiments, the architecture depicted in FIG. 1 is replicated for each separately controlled thermal zone of component 105, such as an inner and outer zone of a wafer chuck (pedestal), chamber showerhead, etc.

As shown, the system 100 includes a heat source control loop 101 and a heat sink control loop 102 affecting the temperature of a component 105. The heat source control loop 101 includes a heater 390 which may be controlled based on a feedback control signal 108A. For exemplary embodiments which compute a control effort based in part on a plasma power input into the plasma processing chamber, the control system 100 further provides a feedforward control signal 107. The control signal 109 sent to the heater driver 390B may therefore be a function (e.g., summation) of both the feedback control signal 108A and the feedforward control signal 107 with an error gain and a power gain applied to the signals 108 and 107, respectively.

Similarly, the heat sink control loop 102 includes a coolant liquid flow 115 which may be controlled based on a feedback control signal 108B. For exemplary embodiments which compute a control effort based in part on a plasma power input into the plasma processing chamber, the control system 100 further provides a feedforward control signal 117. The control signal 119 sent to a coolant liquid control valve(s) 120 therefore may be a function (e.g., summation) of both the feedback control signal 108B and feedforward control signal 117 with an error gain and a power gain applied to the signals 108B and 117, respectively.

The control system 100 includes at least one feedforward transfer function F_{A}(s) and/or F_{B}(s) which takes, as an input, a dependent process parameter, which in this specific example is a plasma power introduced into the plasma process chamber during processing of a workpiece. In one such embodiment, the plasma power is a weighted sum of multiple power inputs to the processing chamber. For example, in one embodiment a weighted sum of Plasma Power equals c1*P1+c2*P2+c3*P3, where P1, P2 and P3 are the bias and/or source powers. The weights c1, c2, and c3 may be any real number, and are typically positive, although in certain embodiments, a weight of a source power is negative where component heating is actually reduced with an increase in source power.

The plasma power input into the feedforward line may be based on any power output by a plasma power source, such as an RF generator, magnetron, etc., that places an appreciable heat load on the temperature controlled system component. The feedforward transfer function F_{A}(s) and/or F_{B}(s) is to provide a control effort opposite in sign to the disturbance transfer function D(s) and compensate an increase in the controlled temperature 150 resulting from the disturbance caused by the plasma source power heat load. The disturbance transfer function D(s) relates a heat load of the plasma power to a rise in the controlled temperature of a plasma processing chamber component having a particular thermal time constant, τ. For example, a step function increase in a plasma power from 0 W to 1000 W at time t may be mapped by the disturbance transfer function D(s) to a component temperature rise over time. The feedforward control signals 107, 117 are coupled with a feedback transfer function G_{1A}(s) and/or G_{1B}(s) providing the feedback control signal 108 for correction of an error signal & corresponding to a difference between the controlled temperature 150 and the setpoint temperature 106.

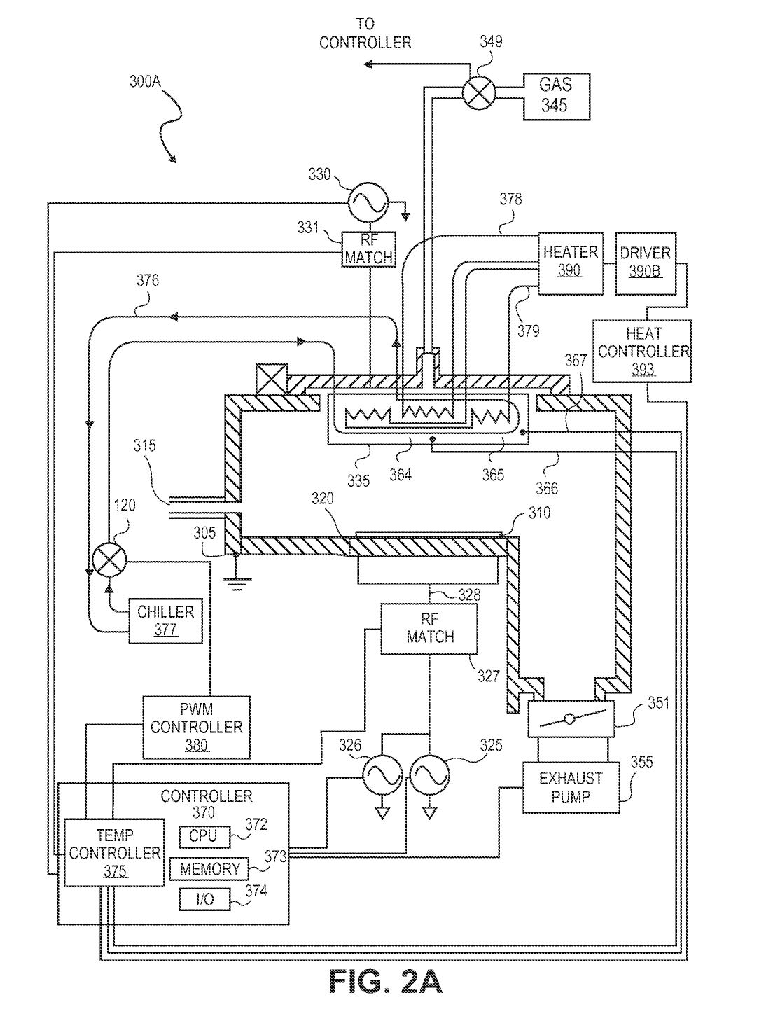

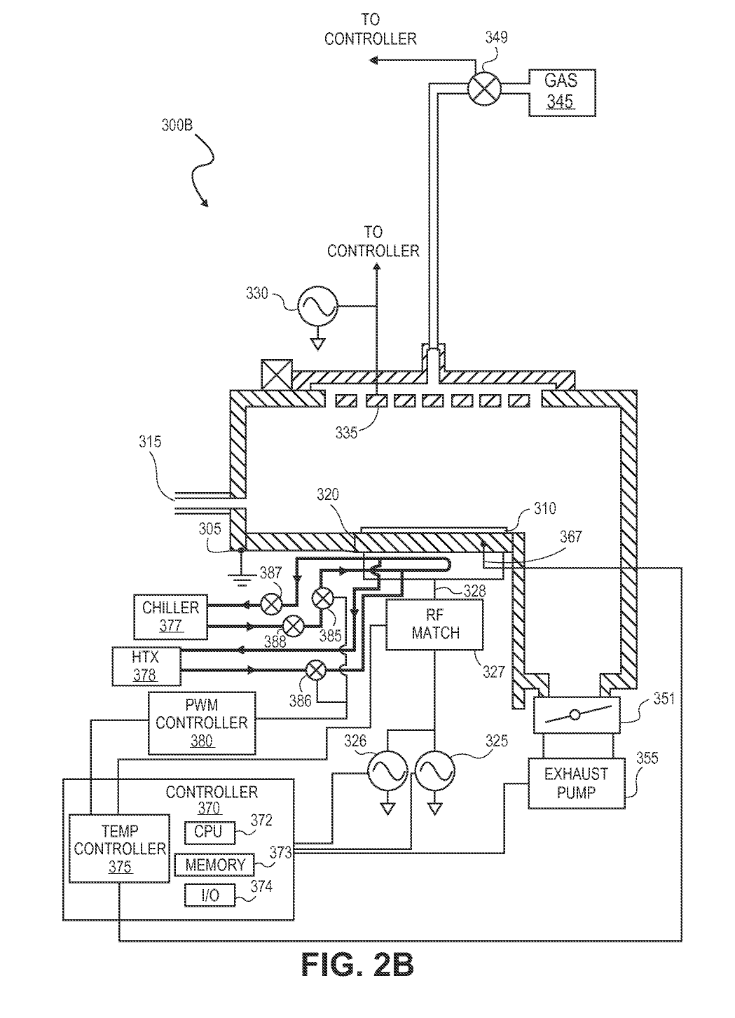

The feedforward control signals 107, 117 along with the setpoint temperature 106, is input to an actuator transfer function G_{1A}(s), G_{1B}(s) and a thermal mass transfer function H(s) to compensate the effect of the disturbance transfer function D(s) on the output controlled temperature. The thermal mass transfer function H(s) includes a function of the heat capacities of the heat sink/source and the temperature-controlled component, etc. The actuator transfer function G_{2B}(s) includes a function of an actuator controlling a heat transfer between the temperature-controlled component 105 and a heat sink (e.g., chiller) and a function of the coolant flow. The illustrated embodiment further includes a function (G_{2A}(s)) of an actuator controlling a heat transfer between the temperature-controlled component 105 and a heat source (e.g., heater element 390 and heater driver 390B in FIG. 2A). The feedforward transfer function F_{A}(s) (or F_{B}(s)) may be implemented with the same actuator as a conventional feedback control system which may already be fitted to an independent closed loop control system, such as a coolant liquid loop. An actuator may be implemented in any manner commonly employed in the art. For the exemplary coolant liquid loop embodiment, an actuator includes one or more valve(s) 120 controlling the coolant liquid flow 115 coupled between the temperature-controlled component 105 and a heat sink (e.g., chiller 377 in FIG. 2B). In a further embodiment, another actuator includes one or more resistive heating element drive power switches (390B in FIG. 2A) coupled to the temperature-controlled component 105.

FIG. 2A illustrates a schematic of a plasma etch system including a temperature controller, where the temperature controlled component 105 of FIG. 1 corresponds to a process gas showerhead, in accordance with an embodiment of the present invention. The plasma etch system 300A may be any type of high performance etch chamber known in the art, such as, but not limited to, Enabler™, MxP®, MxP+™, Super-E™, DPS II AdvantEdge™ G3, E-MAX® chambers, or any other chamber manufactured by Applied Materials of CA, USA. Of course, other commercially available plasma processing chambers may be similarly controlled. Furthermore, while the exemplary embodiments are described in the context of the plasma etch system 300A, it should is noted that the temperature control system architecture described herein is also adaptable to other plasma processing systems (e.g., plasma deposition systems, etc.) which present a heat load on a temperature-controlled component. Also, while many details are provided in the context of temperature control, the embodiments described herein may be readily extended to any measurable plasma process variable which is capable of undergoing an approach to steady state in some appropriate period of time and is associated with a feedforward coefficient that can be altered to effect a change in a manipulated variable to trigger predictable change in a process variable of relevance to the measurable variable.

The plasma etch system 300A includes a grounded chamber 305. A substrate 310 is loaded through an opening 315 and clamped to a chuck 320. The substrate 310 may be any workpiece conventionally employed in the plasma processing art and the present invention is not limited in this respect. The plasma etch system 300A includes a temperature controlled process gas showerhead 335. In the exemplary embodiment depicted, the process gas showerhead 335 includes a plurality of zones 364 (center) and 365 (edge), each zone independently controllable to a setpoint temperature 106 (FIG. 1). Other embodiments have either one zone or more than two zones. For embodiments with more than one zone, there are n heater zones and m coolant zones where n need not be equal to m. For example, in the embodiment depicted, a single cooling loop (m=1) passes through two heater zones (n=2). Process gases, are supplied from a gas source 345 through a mass flow controller 349, through the showerhead 335 and into the interior of the chamber 305. The chamber 305 is evacuated via an exhaust valve 351 connected to a high capacity vacuum pump stack 355.

When plasma power is applied to the chamber 305, a plasma is formed in a processing region over substrate 310. A plasma bias power 325 is coupled to the chuck 320 (e.g., cathode) to energize the plasma. In the exemplary embodiment, the plasma etch system 300A includes a second plasma bias power 326 connected to the same RF match 327 as plasma bias power 325. A plasma source power 330 is coupled through a match 331 to a plasma generating element to provide high frequency source power to inductively or capacitively energize the plasma. Notably, the system component to be temperature controlled by the control system 100 is neither limited to the showerhead 335 or chuck 320, nor must the temperature-controlled component directly couple a plasma power into the process chamber. For example, a chamber liner may be temperature controlled in the manner described herein and a temperature controlled showerhead may or may not function as an RF electrode.

In the exemplary embodiment, the temperature controller 375, as the integrated temperature control software of the system controller 370, is to execute at least a portion of the temperature control algorithms described herein. As such, the temperature controller 375 may be either software or hardware or a combination of both software and hardware. The temperature controller 375 is to output control signals affecting the rate of heat transfer between the showerhead 335 and a heat source and/or heat sink external to the plasma chamber 305 via I/O 374. In the exemplary embodiment, the temperature controller 375 is coupled, either directly or indirectly, to the chiller 377 and the heater element 390. A difference between the temperature of the chiller 377 and the setpoint temperature 106 may be input into the feedforward control line along with the plasma power.

The chiller 377 is to provide a cooling power to the showerhead 335 via a coolant loop 376 thermally coupling the showerhead 335 with the chiller 377. In the exemplary embodiment, one coolant loop 376 is employed which passes a cold liquid (e.g., 50% ethylene glycol at a setpoint temperature of −15° C.) through a coolant channel embedded in both the inner zone 364 and outer zone 365 (e.g., entering proximate to a first zone and exiting proximate to the other zone) of the showerhead 335. The temperature controller 375 is coupled to a coolant liquid pulse width modulation (PWM) driver 380. The coolant liquid PWM driver 380 may be of any type commonly available and configurable to operate the valve(s) 120 for embodiments where those valves are digital (i.e., having binary states; either fully open or fully closed) at a duty cycle dependent on control signals sent by the temperature controller 375. For example, the PWM signal can be produced by a digital output port of a computer (e.g., controller 370) and that signal can be used to drive a relay that controls the valves to on/off positions. In still other embodiments, analog valves providing an infinitely variable flow rate from 0 to a maximum flow rate are utilized with the valve open positions controlled by the temperature controller 375.

For the exemplary embodiment depicted in FIG. 2A, the heater element 390 depicted in FIG. 1 includes first and second electrical resistive heating elements 378, 379. The heating elements 378, 379 may be independently driven based on one or more temperature sensors 366 and 367 (e.g., an optical probe in each of the inner and outer zones 364, 365). The heater driver 390B may be a solid state relay or a semiconductor controlled rectifier (SCR), for example. A heater controller 393 provides PWM functionality analogous to, or in place of, coolant liquid PWM driver 380 to interface the temperature controller 375 with either or both of the heater element(s) 378, 379 and the coolant loop 376. For example, units commercially available from Watlow Electric Manufacturing Company, USA or Azbil/Yamatake, Japan, may be employed as the heater controller 393 and/or coolant liquid PWM driver 380.

FIG. 2B illustrates a schematic of a plasma etch system 300B including a temperature controller, where the temperature controlled component 105 of FIG. 1 corresponds to the workpiece supporting chuck, in accordance with another embodiment of the present invention. Generally, all the components depicted in FIG. 2B having the same reference number as those in FIG. 2A share same structural and functional characteristics. For the embodiment shown in FIG. 2B, the dependent process control parameter is the temperature of the chuck 320 with the control system 100 adapted to control the heat transfer between the chiller 377 and heat exchanger 378, for example through manipulation of the valves 385, 386, 387, and 388. The same feedforward control elements depicted in FIG. 1 are therefore equally applicable to the system 300B.

In operation, for example during execution of a process recipe (e.g., during an active state), duty cycle control commands are sent (e.g., serially) by the temperature controller 375 to the heater controller 393. The heater controller 393 outputs a square wave at the prescribed duty cycle to the heater driver 390B. The heater controller 393 is in an open loop with the temperature controller 375, which sends control commands to the heater controller 393 for automatic control of heater power. For analog embodiments, an analog signal may be sent to the heater driver 390B which would turn on/off the heater element(s) at an appropriate AC phase, for example at zero crossing. For the exemplary embodiment with two heater zones, two channels of the heater controller 393 are output to the heater driver 390B for elements 378, 379. As such, when cooling is required, the valve(s) 120 may be opened (e.g., duty cycle increased) and when heating is required, the valve(s) 120 may be closed (e.g., duty cycle decreased) and resistive heating elements 378 and/or 379 driven.

Notably, the temperature controller 375 need not be contained within, or provided by, the integrated process chamber control software of the system controller 370. Specifically, the functionality of temperature controller 375 may be instead provided as a discrete system. For example, proportional-integral-derivative (PID) controllers, such as, but not limited to those commercially available from Watlow Electric Manufacturing Company or Azbil of Yamatake Corp., may be designed to include additional feedforward inputs, such as the plasma power. The discrete system may further be manufactured to include a processor having the ability to determine a feedforward control effort based on those feedforward inputs. As such, all the embodiments described herein for temperature control may be provided either by the temperature controller 375 as a facet of an integrated process chamber control software or as a component of the PWM driver 380 and/or heater controller 393.

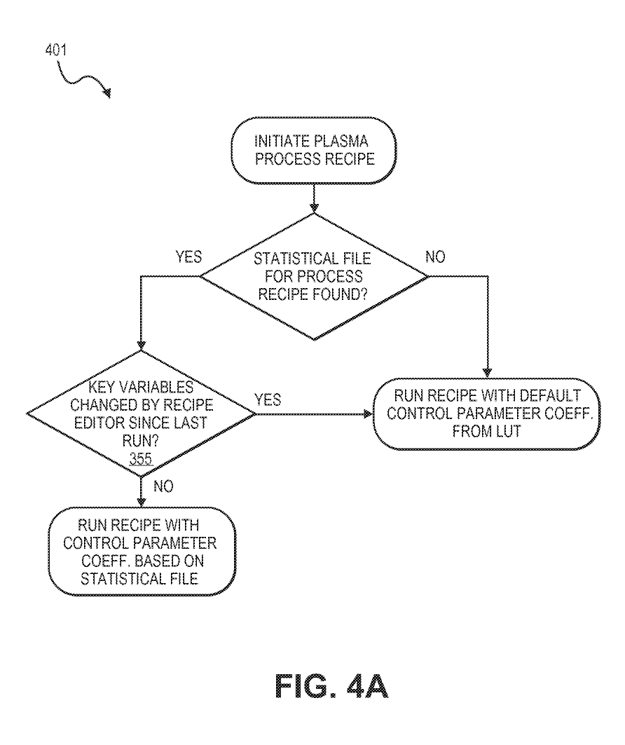

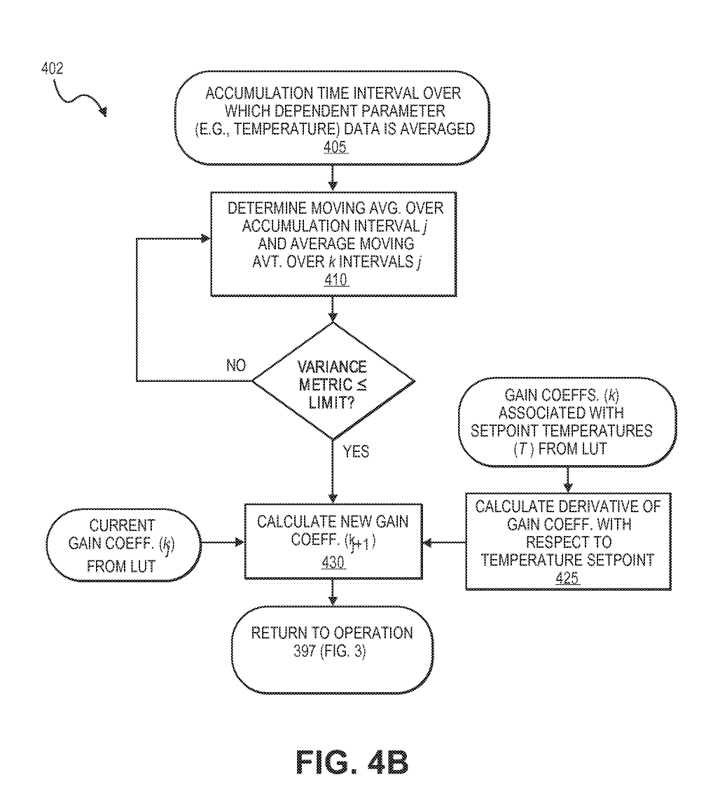

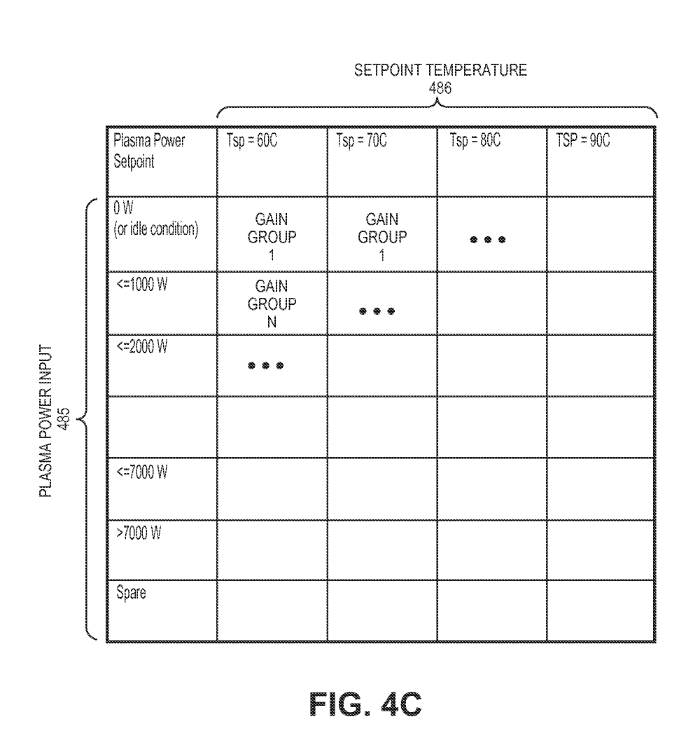

Returning to FIG. 1, during execution of the process recipe, a group of gain values including at least a feedforward control signal gain is determined by the temperature controller 375 based on at least the plasma power input into the chamber 305 for a current recipe step. In one such embodiment, a first group of gain values associated with a key value pairing of the plasma input power and the setpoint temperature is determined for first “step” of the process recipe. FIG. 4C illustrates a gain group lookup table (LUT), in accordance with an embodiment of the present invention. As shown, setpoint temperature 486 is a first key value and plasma power input 485 is a second key value. Gain groups 1, 2, 3, etc. containing gain values for the various control signals in system 100 may be determined from the temperatures 486, plasma power inputs 485, or a pairing of the two corresponding to the conditions of the executing recipe step. The gain group LUT may then be applied as further described elsewhere herein with reference to FIG. 4B.

With the passage of a sample time T_{calc}, the current controlled temperature 150 (FIG. 1) is acquired, the setpoint temperature 106 is acquired, and the plasma input power (bias power, source power, etc.) is acquired. A setpoint temperature for the heat sink may also be acquired. In the exemplary embodiment depicted in FIGS. 2A and 2B, the temperature controller 375 receives a controlled temperature input signal from showerhead sensors for inner and outer zones 364, 365. The temperature controller 375 acquires a setpoint temperature from a process recipe file, for example stored in the memory 373, and the temperature controller 375 acquires a setpoint or measured plasma power. In an embodiment, a measured forward power 328 energizing a plasma in the process chamber 305 at the current time (e.g., after passage of T_{calc}) is input into the feedforward control line as a plasma heat load (e.g., Watts). Plasma power setpoint values (e.g., from a process recipe file stored in a memory 373) may also be utilized as an input to the feedforward control line.

In an exemplary embodiment depicted in FIGS. 2A and 2B, a weighted sum of the plasma powers (e.g., 325, 326, and 330) are inputs with the feedforward transfer function F_{A}(s), and/or F_{B}(s) relating the power input to the feedforward control signal u defining a cooling effort to compensate the disturbance transfer function D(s). The feedforward control signal u, the temperature error signal ε (T-Tₛₚ), the feedback control signal v, and the look-ahead duty cycles are computed at every T_{calc} (e.g., by the CPU 372 instantiating the temperature controller 375 stored in the memory 373). For the exemplary embodiment depicted in FIG. 2A having both an inner and an outer showerhead zone 364, 365, each of the feedforward control signal u, the temperature error signal c, the feedback control signal v is computed for each zone.

In one embodiment, a gain coefficient Kᵤ (e.g., one of the gain coefficients making up a gain group in FIG. 4C) is applied to the feedforward control signal u and a constant gain coefficient Kᵥ is applied to the feedback control signal v. The gain groups containing Kᵥ, Kᵤ provide a system operator a simple interface to access the combined feedforward and feedback control line in two factors for each of the heat source control loop 101 and heat sink control loop 102.

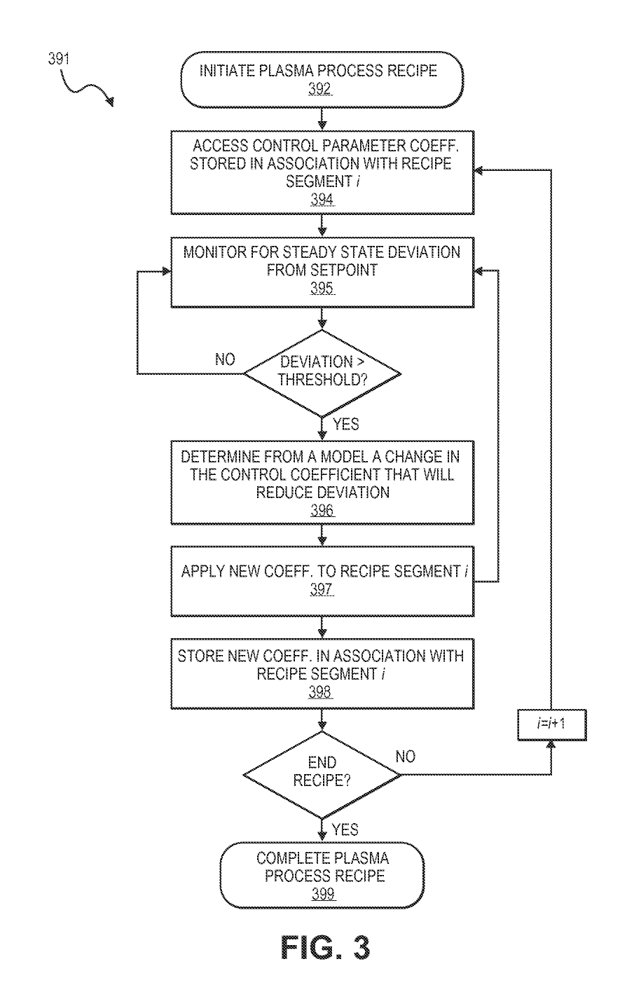

FIG. 3 is a flow diagram illustrating operations in a computer implemented method 391 for adaptive tuning of a control parameter in the plasma etch system depicted in FIGS. 2A and 2B, in accordance with an embodiment of the present invention. The method 391 begins at operation 392 with initiating a plasma process (etch) recipe. At operation 394, a stored control line gain coefficient is accessed either from the LUT 486 based on the values of the independent variables in the ith recipe segment, or from an entry in a statistical file associated with the processing system, the process recipe, and the ith segment of the process recipe. Generally, entries in the statistical file are gain coefficient values (e.g., Kᵤ), stored in association with a particular recipe segment i (e.g., recipe step 1, step 2, step 3, etc.), that were previously tuned by a prior execution of the method 391. Alternatively, the gain coefficient values may be stored in association with independent process parameter values that were employed during the particular recipe segment. In either case, the stored coefficient values are available for subsequent use when the same recipe segment, or same independent process parameters values are employed again. Notably therefore, the method 391 is dynamic, adapting either from a gain coefficient tabulated based on independent variable values as in the LUT 486, or from a prior adaptation of a gain coefficient. Therefore, for a same process performed on a particular system, gain coefficients applied in the control loop can be expected to vary from run-to-run over time as a function of hardware condition, re-configuration, etc.

FIG. 4A is a flow diagram further illustrating computer-implemented operations performed at operation 392, in accordance with an embodiment of the present invention. Where no statistical file for a particular process recipe is found, the process recipe is run with the default control parameter gain coefficients defined in the LUT. Where a statistical file is found, a comparison of key variable values (e.g., bias powers, source power, inner/outer temperature setpoint, etc.) stored in the statistical file are compared to those of the process recipe being executed. If one or more of those variables differs, then the process recipe has been edited since last run, and again the process recipe is run with the default control parameter gain coefficients defined in the LUT. However, if no change in the key variables has occurred, the gain coefficient entries in the statistical file are utilized in the parameter control algorithm.

Returning to FIG. 3, the method 391 continues at operation 395, where the system monitors for a steady state deviation from the process parameter setpoint. As further illustrated in FIG. 1, a steady state error detector 180 is coupled to the feedback control signal 108 and is to detect when the temperature error signal ε (T-Tₛₚ) satisfies a steady state error criteria. When that criteria is satisfied (e.g., deviation from setpoint exceeds a threshold), a change to at least one gain coefficient is determined at operation 396 based on a system model. In embodiments, the model relates a change in the gain coefficient with a change in the controlled dependent process parameter (e.g., ΔKᵤ/ΔT). The system (e.g., modifier 190 in FIG. 1) then updates at least one feedforward gain coefficient to the newly determined coefficient. The modified gain coefficient is then applied, for example to the feedforward control signal 107 and/or 117, so as to modify the control effort in a manner that is expected to reduce the error signal.

In the exemplary embodiment, the newly determined gain coefficient is applied to the current recipe segment (i) at operation 397 (FIG. 3). Such gain coefficient modification is referred to herein as “adaptive process control parameter tuning” and may be substantially real time. At operation 398, the new gain coefficient is stored in association with segment i of the process recipe. In the exemplary embodiment, the new gain coefficient is stored to a statistical file associated with a particular plasma processing (etching) system and process recipe, separate from the LUT 486. With the new gain coefficient active in the control loop, the method 391 then proceeds further monitoring for a new steady state error during execution of the remainder of the recipe segment (i) by looping back to operation 395 until execution of the process recipe advances to the next recipe segment (i+1).

Upon advancing to the next recipe segment (i+1), the method 391 returns to operation 394 for a subsequent iteration beginning with accessing a new control parameter gain coefficient, either from the LUT 486 based on the independent variable values, or from the statistical file. The method 391 proceeds in this manner through all recipe segments until the entire process recipe is executed and workpiece processing completed at operation 399. In embodiments, the method 391 is performed as production runs on a plasma processing chamber are executed. As such, control parameter gain coefficients are updated continuously (e.g., within a wafer process and between wafers).

FIG. 4B is a flow diagram illustrating operations invoked by the computer implemented method 391, in accordance with an embodiment of the present invention. Referring to FIG. 4B, the computer implemented method 402 begins with accessing an accumulation time variable value that is to define an interval of time (j) over which all measured response data (e.g., temperature data 150 in FIG. 1) is to be grouped. In other words, the accumulation time interval defines a subset size for time series data collected from the response variable. Alternatively, a predetermined number of data collection points may be similarly defined. While the accumulation time may vary widely depending on the nature of the plasma processing performed on a workpiece, an exemplary range is 0.5-20 seconds.

At operation 410, the measured response data is passed through a low pass filter to smooth the measurement data over a sample of data points. This sample metric is then compared to a metric associated with larger data population to determine if a steady state has been reached. In the exemplary embodiment, a sample moving average is determined over the accumulation interval j, with the sample average recalculated upon the passage of every time interval j. The sample moving average can be a simple moving average, or a weighted moving average, etc. The sample moving average values are stored to memory, for example in an array or FIFO buffer. A grand average temperature is further calculated on every upon the passage of every time interval j. In the exemplary embodiment, the grand average is a moving average of the sample moving averages over k of intervals j. For example, an average of all the sample moving averages present in the FIFO buffer may be determined each time a sample moving average is added to the FIFO stack.

The sample metric is then compared to the larger data population metric with the difference thresholded by a variance metric. Once the variance metric is below the threshold value, the algorithm concludes temperature is at steady state. In the exemplary embodiment, a “moving variance metric” is:

$${\sum }_{n - ( num samples - 1 )}^{n} \vert Sample {Avg}_{n} - Grand {Avg}_{k} \vert ,$$

where the moving variance metric is a “pseudo variance” because absolute value, not square, is utilized. Where the variance metric as defined here is small in value, it can be concluded that both the first and second time derivatives (of measured temperature) are close to zero, and therefore the controlled parameter (e.g., temperature 150 in FIG. 1) deemed to be at “steady state.”

Upon detecting steady state, the method 402 proceeds to operation 430 where a new gain coefficient (e.g., feedforward coefficient Kᵤ) is calculated. Generally, the new gain coefficient may be determined based on a function relating a change in the gain coefficient with a change in the controlled dependent process parameter such that a change in the gain coefficient can be determined from the error between the dependent parameter setpoint and the measured value (e.g., feedback control signal 108 for correction of an error signal ε corresponding to a difference between the controlled temperature 150 and the setpoint temperature 106). In the exemplary embodiment, where the LUT 486 represents the gain coefficient Kᵤ as a function of the weighted heating power and temperature setpoint, the dependence of Kᵤ on temperature setpoint can be determined from entries in the LUT 486. In one technique, the new Kᵤ is determined as

$${K}_{u , j + 1} = {K}_{u , j} - Δ {K}_{u} , \\ where$$

$$Δ {K}_{u} = A ɛ ( \frac{δ {K}_{u}}{δ T} ) ,$$

where A is a convergence constant and

$$\frac{δ {K}_{u}}{δ T}$$

is a finite-element approximation of the derivative of the gain coefficient Kᵤ taken with respect to the temperature setpoint, which is obtained using appropriate elements in the gain coefficient LUT 486 at operation 425. If the search for K_{u,j+1} iterates, the value of

$$\frac{δ {K}_{u}}{δ T}$$

doesn't change from one iteration to the next. That is, LUT values of Kᵤ are always used for purpose of computing derivative. As such, the LUT 486 is utilized as a model in the adaptation algorithm as a reasonably good, but not perfectly accurate tabulation for a particular plasma processing chamber or any specific plasma recipe.

For embodiments employing two or more temperature zones, and unequal setpoints exist in the recipe, the automated method 402 will perform Kᵤ adjustments to reach those setpoints, and it can be expected that the algorithm may change the Kᵤ of the hotter zone such that the Kᵤ value becomes >0 while Kᵤ values are typically ≦0 in the LUT 486. When inner and outer zone Kᵤ are opposite signs, the hot and cold chiller begin mutually trying to chill and heat each other (respectively), because of the inter-zone thermal coupling of the ESC. Positive Kᵤ values may be advantageously restricted so that the hot-side driving signal can never be forced overly positive when cold-side driving signal of other temperature zone is negative. The restriction can be done by applying a limit to the K_{u,j+1} value as soon as it is calculated.

With the new gain coefficient calculated, the method 402 returns to operation 397 in FIG. 3 for the new coefficient to be implemented in the current process recipe segment and stored for future use whenever this particular process recipe segment is executed (assuming a recipe edit has not since occurred).

Noting the method 402 is contingent on a steady state condition occurring during plasma processing, the duration of a recipe segment is to be at least long enough for such a steady state condition to occur if the gain coefficient is to be adapted from the initial value access from the LUT 486. As such, in one advantageous embodiment a calibration service routine entails loading a workpiece (e.g., dummy wafer), and iteratively running a specified process recipe of sufficient time. In one such embodiment, feedback is disabled (e.g., with Kᵥ set to zero), such that the method 391 is performed, method 402 invoked, and Kᵤ updated until steady state temperature achieves the target setpoint. Following execution of the plasma process, the adapted gain coefficient Kᵤ is stored. The service routine may further perform this same process on a matrix of process conditions (e.g., varying bias, source power, temperature setpoints, pressure, etc.) until the statistical file is well populated with gain coefficients covering a predetermined process space (e.g., associated with production recipes executed on the particular chamber).

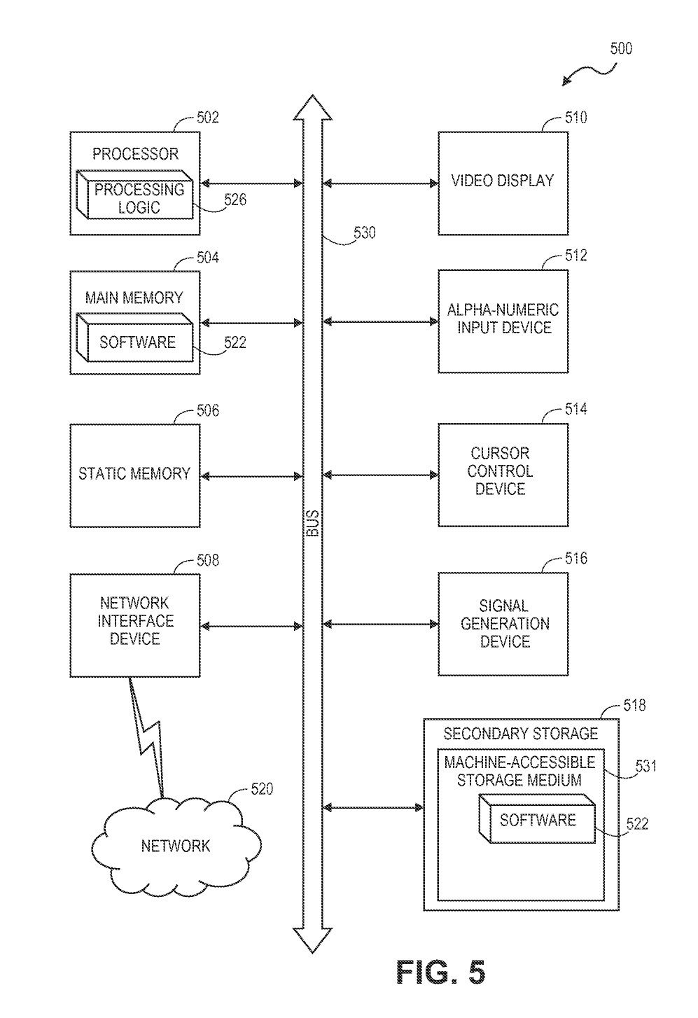

FIG. 5 illustrates a diagrammatic representation of a machine in the exemplary form of a computer system 500 which may be utilized to perform the temperature control operations described herein. In one embodiment, the computer system 500 may be provisioned as the controller 370 in the plasma etch systems 300A or 300B and provisioned to implement the automated methods 391, 401, 402. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a server, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

The processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. The processor 502 may also be one or more special-purpose processing devices such as an application specific integrated circuit (ASIC), a field programmable gate array (FPGA), a digital signal processor (DSP), network processor, or the like. The processor 502 is configured to execute the processing logic 526 for performing the temperature control operations discussed elsewhere herein.

The computer system 500 may further include a network interface device 508. The computer system 500 also may include a video display unit 510 (e.g., a liquid crystal display (LCD) or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a non-transitory computer-readable storage medium) 531 on which is stored one or more sets of instructions (e.g., software 522) embodying any one or more of the temperature control algorithms described herein. The software 522 may also reside, completely or at least partially, within the main memory 504 and/or within the processor 502 during execution thereof by the computer system 500, the main memory 504 and the processor 502 also constituting machine-readable storage media. The software 522 may further be transmitted or received over a network 520 via the network interface device 508.

The machine-accessible storage medium 531 may further be used to store a set of instructions for execution by a processing system and that cause the system to perform any one or more of the temperature control algorithms described herein. Embodiments of the present invention may further be provided as a computer program product, or software, which may include a machine-readable medium having stored thereon instructions, which may be used to program a computer system (or other electronic devices) to control a plasma processing chamber temperature according to the present invention as described elsewhere herein. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, and flash memory devices, etc.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. Accordingly, the specification and drawings are to be regarded in an illustrative sense rather than a restrictive sense. The scope of the invention should, therefore, be determined with reference to the appended claims, along with the full scope of equivalents to which such claims are entitled.

What is claimed is:

1. A computer-implemented method for adaptively controlling a process parameter for a plasma processing chamber, the method comprising:
controlling a dependent process parameter value, at least in part, with a feedforward control signal;
determining the process parameter to be in a steady state condition with a value that deviates from a setpoint of the dependent process parameter value; and
modifying a gain coefficient of the feedforward control signal based on a model function relating a change in the gain coefficient with a change in the dependent process parameter value.

2. The method of claim 1, further comprising:
determining a value of an independent process parameter when the chamber is in an active state executing a plasma process recipe; and
determining the feedforward control signal gain coefficient, based at least in part on the independent process parameter value.

3. The method of claim 2, wherein modifying the gain coefficient of the feedforward control signal further comprises changing the gain coefficient while the chamber is in the active state executing the plasma process recipe.

4. The method of claim 2, further comprising:
storing to a file the modified gain coefficient of the feedforward control signal in association with a particular segment of the plasma process recipe having the independent process parameter value, wherein controlling the dependent process parameter value during a subsequent execution of the plasma process recipe further comprises accessing the modified gain coefficient of the feedforward control signal stored in the file.

5. The method of claim 2, wherein determining the feedforward control signal gain coefficient further comprises accessing a lookup table associating gain coefficients as a function of dependent process parameter setpoints and values of the independent process parameter.

6. The method of claim 5, wherein the model function is derived from lookup table entries.

7. The method of claim 6, wherein the model function comprises an estimate of a change in the gain coefficient as a function of a change in the dependent process parameter setpoint.

8. The method of claim 7, wherein the model function comprises an estimate of the derivative of the gain coefficient with respect to the dependent process parameter setpoint.

9. The method of claim 7, wherein modifying the feedforward control signal gain coefficient further comprises evaluating the model function to determine a change in the gain coefficient corresponding to a change in the setpoint equal to an amount by which the dependent process parameter value deviates from the setpoint.

10. The method of claim 1, wherein the independent process parameter value is a plasma power energizing a plasma during an active state, and wherein the dependent process parameter value is a chamber component temperature.

11. The method of claim 10, wherein the plasma power comprises a first bias power input to a chuck configured to support a workpiece and wherein the feedforward control signal comprises a transfer function between the first bias power input and the chuck or workpiece temperature, the method further comprising:
controlling a heat transfer liquid flow to the chuck with the feedforward control signal.

12. A computer readable media with instructions stored thereon, which when executed by a processing system, cause the system to perform the method comprising:
determining a value of an independent process parameter when the chamber is in an active state executing a plasma process recipe;
determining a feedforward control signal gain coefficient, based at least in part on the independent process parameter value;
controlling a dependent process parameter value, at least in part, with a feedforward control signal employing the feedforward control signal gain coefficient;
determining the dependent process parameter to be in a steady state condition with a value that deviates from a setpoint for the dependent process parameter; and
modifying the feedforward control signal gain coefficient based on a model function relating a change in the gain coefficient with a change in the dependent process parameter value.

13. The media of claim 12, wherein determining the feedforward control signal gain coefficient further comprises accessing a lookup table associating gain coefficients with independent process parameter values, and wherein the instructions cause the system to store the modified feedforward control signal gain coefficient in association with a particular segment of the plasma process recipe, and access the stored modified feedforward control signal gain coefficient during a subsequent execution of the plasma process recipe.

14. A plasma processing apparatus, comprising:
a plasma power source coupled to a process chamber to energize a plasma during processing of a workpiece disposed in the process chamber;
a process controller to control an independent process parameter and a dependent process parameter, wherein the controller is to:
control the dependent process parameter with a feedforward control loop based at least in part on the independent process parameter; and
update a gain coefficient of the feedforward control loop upon determining the dependent process parameter is in a steady state condition with a value that deviates from a setpoint.

15. The apparatus of claim 14, wherein the controller is to:
determine a value of the independent process parameter when the chamber is in an active state executing a plasma process recipe;
determine the gain coefficient, based at least in part on the independent process parameter value; and
change the gain coefficient while the chamber is in the active state executing the plasma process recipe.

16. The apparatus of claim 15, wherein the controller is to:
store the modified control signal gain coefficient in association with a particular segment of the plasma process recipe having the independent process parameter value;
control the dependent process parameter value during a subsequent execution of the plasma process recipe by accessing the stored modified gain coefficient.

17. The apparatus of claim 14, wherein the controller is to determine the feedforward control signal gain coefficient by accessing a lookup table associating gain coefficients as a function of setpoints of the dependent process parameter and values of the independent process parameter.

18. The apparatus of claim 17, wherein the controller is to generate a model function from lookup table entries.

19. The apparatus of claim 18, wherein the model function comprises an estimate of a change in the gain coefficient as a function of a change in the dependent process parameter setpoint.

20. The apparatus of claim 14, wherein the feedforward control signal is to compensate a plasma heating of a temperature-controlled component of the plasma processing apparatus, and wherein the temperature controller is communicatively coupled to the plasma power source and wherein the independent process parameter is a plasma power input acquired from the plasma power source.
